(19) United States
(12) Patent Application Publication
(10) Pub. No.: US 2013/0272027 A1
(43) Pub. Date: Oct. 17, 2013

(54) Method for Manufacturing LED Light Bar and LED Light Bar and Backlight Module

(71) Applicants: Chechang Hu, Shenzhen City (CN); Hu He, Shenzhen City (CN)

(72) Inventors: Chechang Hu, Shenzhen City (CN); Hu He, Shenzhen City (CN)

(73) Assignee: Shenzhen China Star Optoelectronics Technology Co., LTD., Shenzhen City, Guangdong (CN)

(21) Appl. No.: 13/515,268

(22) PCT Filed: Apr. 18, 2012
(86) PCT No.: PCT/CN12/74229

§ 371 Date: Jun. 11, 2012

(30) Foreign Application Priority Data
Apr. 11, 2012 (CN) 201210104426.2

(51) Int. Cl. F21V 21/00; G09F 13/04; H01L 21/66; F21V 8/00

(52) U.S. Cl. 362/612; 362/97.1; 362/217.14; 438/15; 257/E21.521

(57) ABSTRACT

The present invention provides a method for manufacturing LED light bar, which includes the following steps: (1) providing light-emitting dies of different sizes; (2) measuring luminous intensities of the light-emitting dies; (3) selecting among the light-emitting diodes ones of which the luminous intensities are different from each other by less than 5%; (4) encapsulating the selected ones of the light-emitting dies to form LED lights, which are of substantially identical encapsulated size; and (5) mounting and electrically connecting the LED lights to a printed circuit board to form an LED light bar. The method for manufacturing LED light bar according to the present invention uses light-emitting dies of different sizes so as to improve utilization rate of an entire wafer and effectively reduce the manufacture cost.

### BACKGROUND OF THE INVENTION

1. Field of the Invention

The present invention relates to the field of liquid crystal displaying, and in particular to a method for manufacturing an LED (Light-Emitting Diode) light bar and an LED light bar made with the method and a backlight module using the LED light bar.

2. The Related Arts

A liquid crystal display (LCD) has a variety of advantages, such as compact device size, low power consumption, and being free of radiation, and is thus widely used. Most of the LCDs that are currently available in the market are backlighting LCDs, which comprise a liquid crystal display panel and a backlight module. The working principle of the liquid crystal display panel is that liquid crystal molecules are interposed between two parallel glass substrates and a plurality of vertical and horizontal fine electrical wires is arranged between the two glass substrates, whereby the liquid crystal molecules are controlled to change direction by application of electricity in order to refract light emitting from the backlight module for generating images. Since the liquid crystal display panel itself does not emit light, light must be provided by the backlight module in order to normally display images. Thus, the backlight module is one of the key components of an LCD. The backlight module can be classified as two types, namely side-edge backlight module and direct backlight module, according to the position where light gets incident. The direct backlight module arranges a light source, such as a cold cathode fluorescent lamp (CCFL) or a light-emitting diode (LED) at the back side of the liquid crystal display panel to form a planar light source that directly provides lighting to the liquid crystal display panel. The side-edge backlight module arranges an LED light bar of a backlight source at an edge of a back panel that is located rearward of one side of the liquid crystal display panel. The LED light bar emits light that enters a light guide plate through a light incident face of the light guide plate and is projected out through a light exit face after being reflected and diffused to thereby form a planar light source to be provided to the liquid crystal display panel.

Referring to FIG. 1, a conventional side-edge backlight module comprises a backplane 100, an LED light bar 200 arranged inside the backplane 100, a reflector plate 300 arranged inside the backplane 100, a light guide plate 400 disposed on the reflector plate 300, an optic film assembly 500 disposed on the light guide plate 400, and a mold frame 600 mounted to the backplane 100. The LED light bar 200 serves as a backlight source and the light guide plate 400 functions to conduct light so that the LED light bar 200 that is seemingly like a spot light source is converted to a planar light source.

Referring to FIG. 2, a conventional direct backlight module comprises a backplane 100′, LED light bars 200′ arranged inside the backplane 100′, a reflector plate 300′ arranged inside the backplane 100′, a diffusion plate 400′ arranged above the reflector plate 300′, an optic film assembly 500′ disposed on the diffusion plate 400′, and a mold frame 600′ mounted to the backplane 100′. The LED light bars 200′ serve as light sources that are mixed in the reflector plate 300′ and are subjected to homogenization by the diffusion plate 400′ and the optic film assembly 500′ so that the LED light bars 200′ that are seemingly like spot light sources are converted to a planar light source.

However, each LED light (see FIG. 3) contained in each LED light bar of the side-edge backlight module and the direct backlight module comprises a carrier frame 210, a light-emitting die 220 mounted to the carrier frame 210, and an encapsulation resin 230 the encapsulates the light-emitting die 220. The encapsulation resin 230 is often mixed with fluorescent powders. Light projecting from the LED light is composed of two components including light emitting from the light-emitting die 220 and light generated by excitation of the fluorescent powder. The luminous power of the light-emitting die 220 is a major factor that determines the light intensity of the LED light.

The light-emitting dies that are currently available are formed by cutting through a wafer of a relatively large size. Forming light-emitting dies of different sizes through such a cutting process show different cutting utilization rate. The smaller the size of the light-emitting dies is, the higher the cutting utilization rate will be and the lower the cost will be. For a specific backlight module, the luminous intensity of the LED light must be limited within a given range. To satisfy the requirements for both brightness and homogeneity, light-emitting dies of substantially the same size are selected and identical encapsulation is applied. This makes the light-emitting dies that are not of such a size unusable and leads to a waste of cost.

### SUMMARY OF THE INVENTION

Thus, an object of the present invention is to provide a method for manufacturing an LED light bar, which selects light-emitting dies that are used to make the LED light bar according to the luminous intensity of the light-emitting die so as to effectively reduce the manufacture cost.

Another object of the present invention is to provide an LED light bar, which uses light-emitting dies of different sizes and thus takes full advantage of the light-emitting dies, reducing the waste of the light-emitting dies in the manufacture process and lowering the manufacture cost.

A further object of the present invention is to provide a backlight module that uses LED bars made of light-emitting dies of inconsistent sizes so as to reduce the cost while ensuring desired homogeneity of illumination.

To achieve the objects, the present invention provides a method for manufacturing an LED light bar, comprising the following steps:

Step 1: providing light-emitting dies of different sizes;

Step 2: measuring luminous intensities of the light-emitting dies;

Step 3: selecting among the light-emitting diodes ones of which the luminous intensities are different from each other by less than 5%;

Step 4: encapsulating the selected ones of the light-emitting dies to form LED lights, which are of substantially identical encapsulated size; and

Step 5: mounting and electrically connecting the LED lights to a printed circuit board to form an LED light bar.

The present invention also provides an LED light bar, which comprises a printed circuit board and a plurality of LED lights mounted to and electrically connected to the printed circuit board. Each of the LED lights comprises a light-emitting die. The light-emitting dies of the plurality of LED lights are of at least two sizes. The luminous intensities of the light-emitting dies are different from each other by less than 5%.

The plurality of LED lights is of an identical encapsulated size.

Each of the LED lights comprises a carrier frame, copper foils mounted to the carrier frame, and an encapsulation resin. The light-emitting die is arranged inside the carrier frame and electrically connected by gold wires to the copper foils. The encapsulation resin encapsulates the light-emitting die in the carrier frame.

The present invention also provides a backlight module, which comprises a backplane and an LED light bar mounted in the backplane. The LED light bar comprises a printed circuit board and a plurality of LED lights mounted to the printed circuit board. Each of the LED lights comprises a light-emitting die. The light-emitting dies of the plurality of LED lights are of at least two sizes. The luminous intensities of the light-emitting dies are different from each other by less than 5%. The plurality of LED lights is of an identical encapsulated size.

Each of the LED lights comprises a carrier frame, copper foils mounted to the carrier frame, and an encapsulation resin. The light-emitting die is arranged inside the carrier frame and electrically connected by gold wires to the copper foils. The encapsulation resin encapsulates the light-emitting die in the carrier frame.

The backplane comprises a bottom plate and a side plate perpendicularly mounted to the bottom plate.

The backlight module further comprises a light guide plate disposed above the bottom plate, a reflector plate disposed between the bottom plate and the light guide plate, optic films disposed on the light guide plate, and a mold frame mounted to the backplane. The LED light bar is mounted to the side plate.

Alternatively, the backlight module further comprises a diffusion plate disposed above the bottom plate, a reflector plate disposed between the bottom plate and the diffusion plate, optic films disposed on the diffusion plate, and a mold frame mounted to the backplane. The LED light bar is mounted to the bottom plate and located below the diffusion plate.

The efficacy of the present invention is that the present invention provides a method for manufacturing LED light bar that uses light-emitting dies of different sizes so as to improve utilization rate of an entire wafer and effectively reduce the manufacture cost. The present invention provides an LED light bar, which is formed by combining light-emitting dies that are of different sizes and have luminous intensities of limited variation so as to reduce waste of light-emitting dies in manufacturing LED lights and lower the manufacture cost. The present invention provides a backlight module, which uses the LED light bar described above so as to reduce the manufacture cost while ensuring homogeneity of illumination.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of an embodiment of the present invention, with reference to the attached drawings. In the drawings:

FIG. 1 is a schematic view showing the structure of a conventional side-edge backlight module;

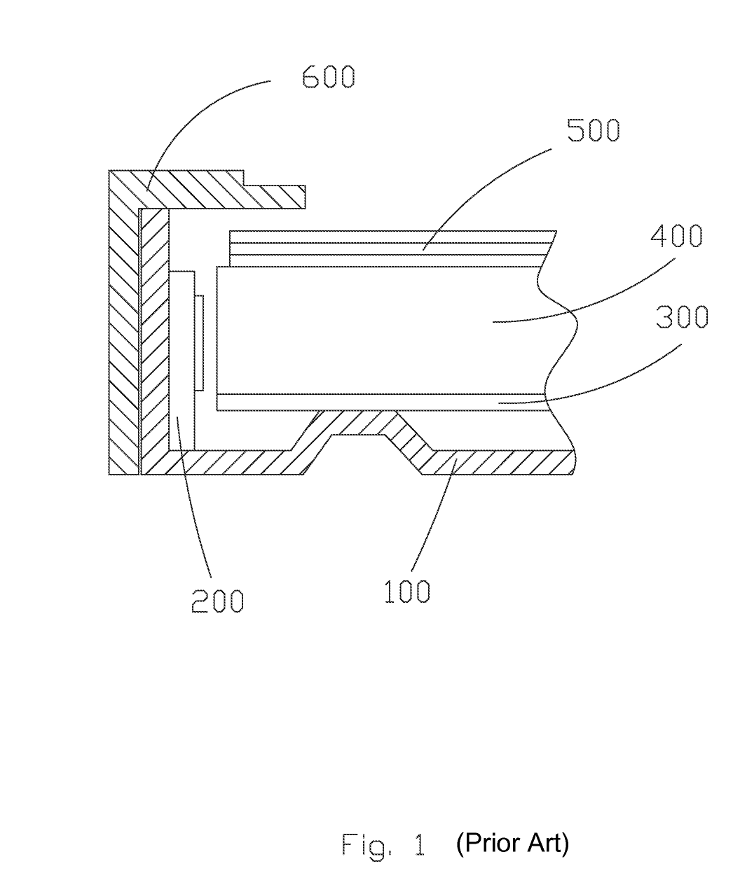

FIG. 2 is a schematic view showing the structure of a conventional direct backlight module;

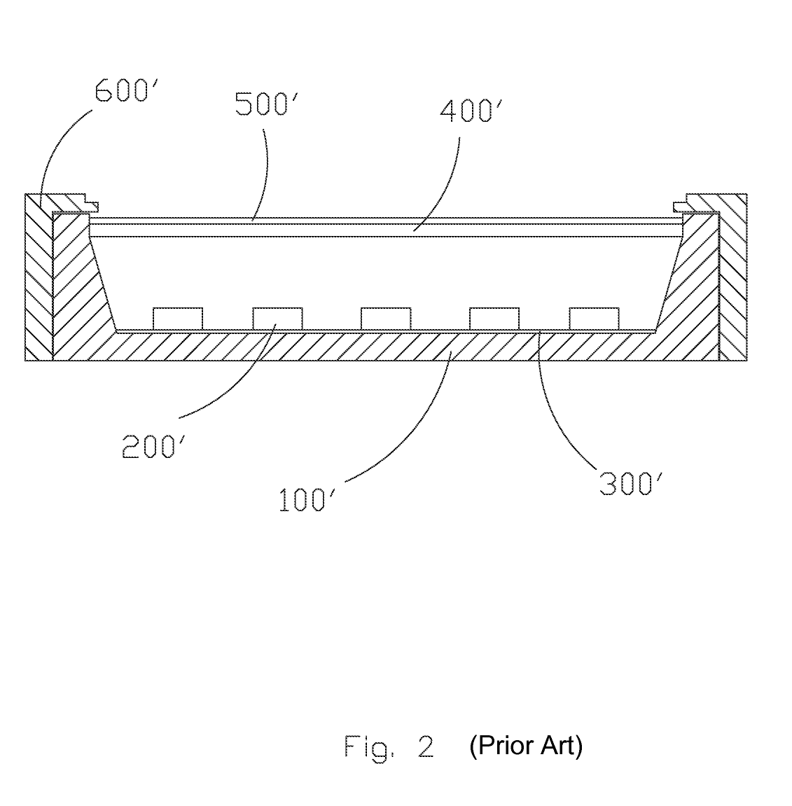

FIG. 3 is a schematic view showing the structure of a conventional LED light;

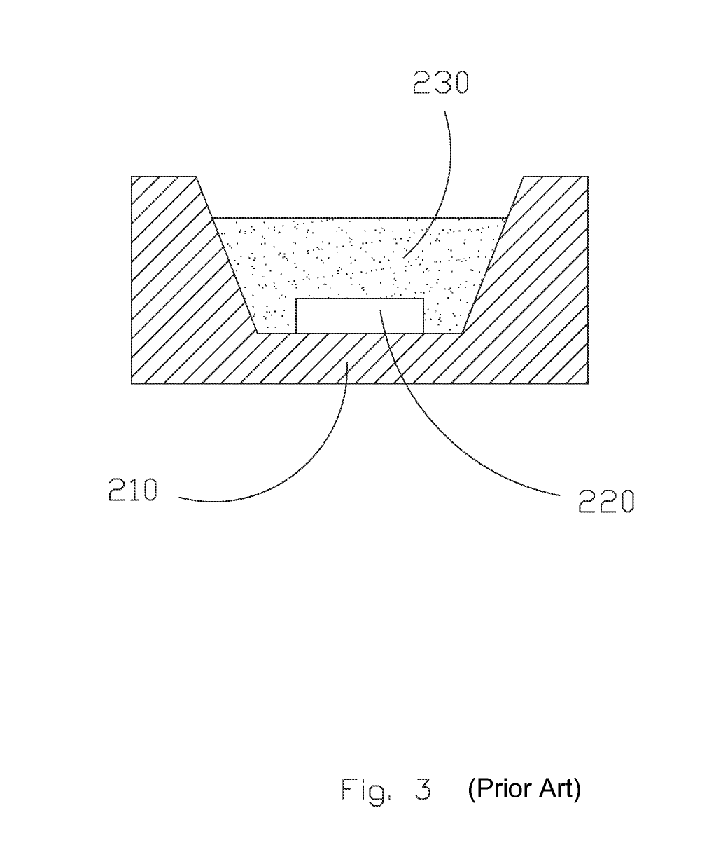

FIG. 4 is a flow chart illustrating a method for manufacturing an LED light bar according to the present invention;

FIG. 5 is a schematic view showing the structure of an LED light bar according to the present invention;

FIG. 6 is a schematic view showing the structure of a backlight module according to an embodiment of the present invention; and

FIG. 7 is a schematic view showing the structure of a backlight module according to another embodiment of the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

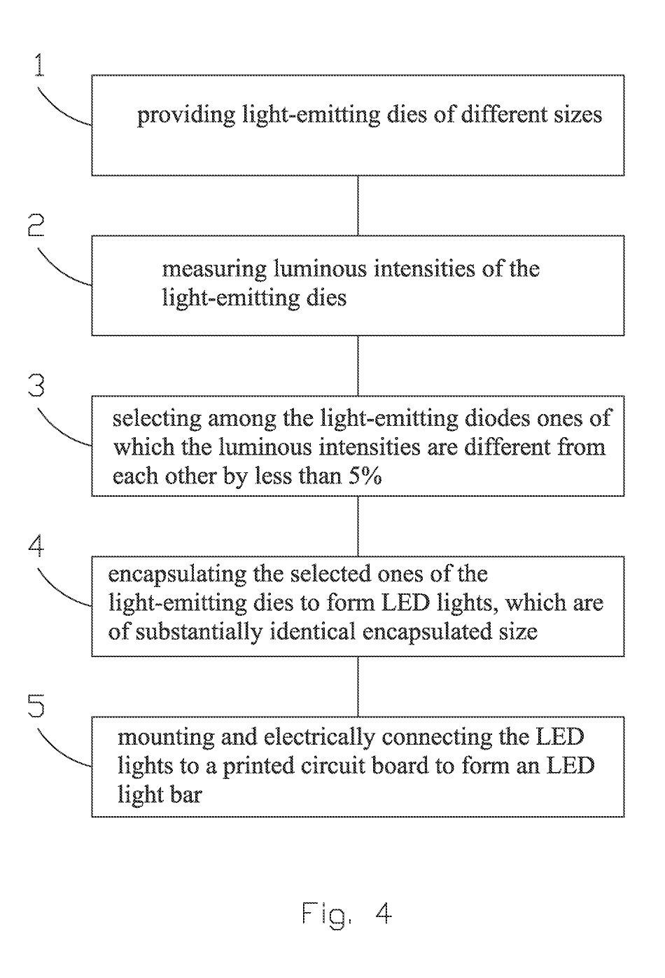

Referring to FIG. 4, the present invention provides a method for manufacturing an LED (Light-Emitting Diode0 light bar, comprising the following steps:

Step 1: providing light-emitting dies of different sizes;

Step 2: measuring luminous intensities of the light-emitting dies;

Step 3: selecting among the light-emitting dies ones of which the luminous intensities are within a predetermined luminous intensity range, the differences among the luminous intensities of the selected light-emitting dies being less than 5%;

Step 4: encapsulating the selected ones of the light-emitting dies to form LED lights, which are of substantially identical encapsulated size; and

Step 5: mounting and electrically connecting the LED lights to a printed circuit board to form an LED light bar.

The method for manufacturing an LED light bar according to the present invention uses light-emitting dies of different sizes so as to improve utilization rate of an entire wafer and effectively reduce the manufacture cost.

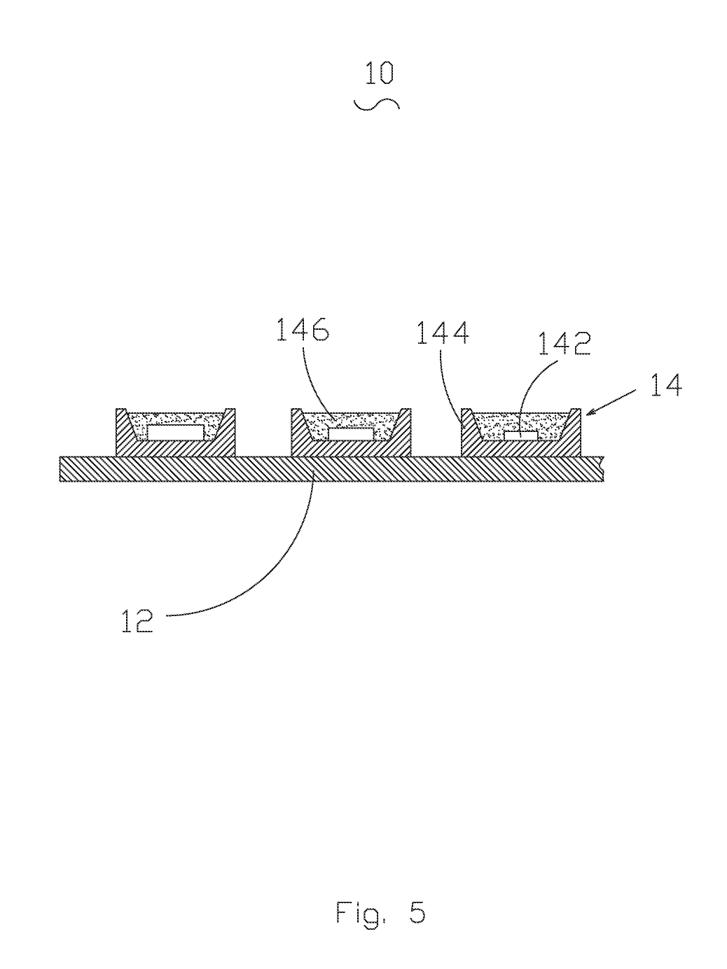

Referring to FIG. 5, the present invention provides an LED light bar 10, which comprises a printed circuit board 12 and a plurality of LED lights 14 mounted to and electrically connected to the printed circuit board 12 in which the LED lights 14 are of an identical encapsulated size.

Each of the LED lights 14 comprises a light-emitting die 142 and the light-emitting dies 142 of the plurality of LED lights 14 are of at least two sizes. Differences among the luminous intensities of the light-emitting dies 142 are less than 5%.

Generally, the larger the size of the light-emitting die 142 is, greater the luminous intensity will be. However, due to variation of manufacturing process, the light-emitting dies 142 have various luminous intensities that are located within a predetermined range of variation. For a specific planar light source that is composed of light sources formed of the LED light bar 10, it only needs the variation of luminous intensity of each LED light 14 located within a range of 5% to ensure homogeneity of illumination of the planar light source. This allows the present invention to use, in combination, light-emitting dies 142 of different sizes to form an LED light bar 10, which is then subjected to identical encapsulation operation so as to provide multiple LED lights 14 of the same encapsulation size, eliminating waste of material and reducing manufacture cost.

Each LED light 14 also comprises a carrier frame 144, copper foils (not shown) mounted to the carrier frame, and an encapsulation resin 146. The light-emitting die 142 is arranged inside the carrier frame 144 and is electrically connected by gold wires (not shown) to the copper foils. The encapsulation resin 146 encapsulates the light-emitting die 142 in the carrier frame 144. The encapsulation resin 146 contains fluorescent powders mixed therein to improve the luminous intensity of the LED light 14.

The present invention provides an LED light bar, which is formed by combining light-emitting dies that are of different sizes and have luminous intensities of limited variation so as to reduce waste of light-emitting dies in manufacturing LED lights and lower the manufacture cost.

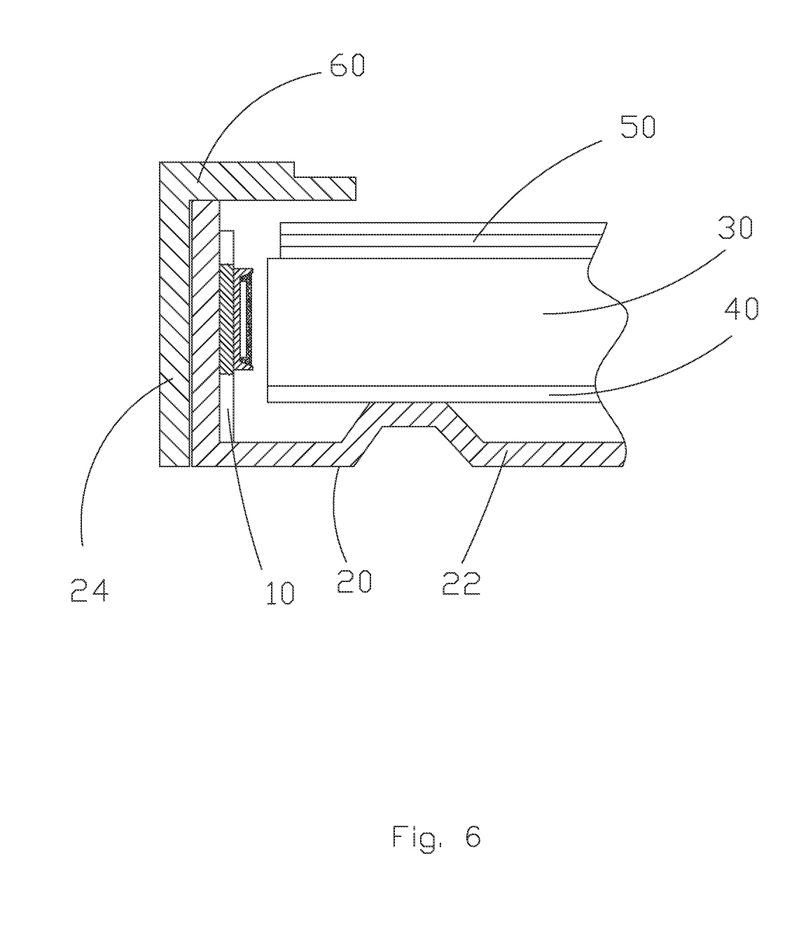

Referring to FIGS. 5 and 6, the present invention also provides a backlight module, which comprises a backplane 20 and an LED light bar 10 mounted in the backplane 20. The backplane 20 comprises a bottom plate 22 and a side plate 24 perpendicularly mounted to the bottom plate 22. The LED light bar 10 comprises a printed circuit board 12 and a plurality of LED lights 14 mounted to and electrically connected to the printed circuit board 12. Each of the LED lights 14 comprises a light-emitting die 142 and the light-emitting dies 142 of the plurality of LED lights 14 are of at least two sizes. Differences among the luminous intensities of the light-emitting dies 142 are less than 5%. The plurality of LED lights 14 is of an identical encapsulated size.

Generally, the larger the size of the light-emitting die 142 is, greater the luminous intensity will be. However, due to variation of manufacturing process, the light-emitting dies 142 have various luminous intensities that are located within a predetermined range of variation. For a specific planar light source that is composed of light sources formed of the LED light bar 10, it only needs the variation of luminous intensity of each LED light 14 located within a range of 5% to ensure homogeneity of illumination of the planar light source. This allows the present invention to use, in combination, light-emitting dies 142 of different sizes to form an LED light bar 10, which is then subjected to identical encapsulation operation so as to provide multiple LED lights 14 of the same encapsulation size, eliminating waste of material and reducing manufacture cost.

Each LED light 14 also comprises a carrier frame 144, copper foils (not shown) mounted to the carrier frame, and an encapsulation resin 146. The light-emitting die 142 is arranged inside the carrier frame 144 and is electrically connected by gold wires (not shown) to the copper foils. The encapsulation resin 146 encapsulates the light-emitting die 142 in the carrier frame 144. The encapsulation resin 146 contains fluorescent powders mixed therein to improve the luminous intensity of the LED light 14.

In the instant embodiment, the backlight module further comprises a light guide plate 30 disposed above the bottom plate 22, a reflector plate 40 disposed between the bottom plate 22 and the light guide plate 30, optic films 50 disposed on the light guide plate 30, and a mold frame 60 mounted to the backplane 20. The LED light bar 10 is mounted to the side plate 24 so as to form a side-edge backlight module.

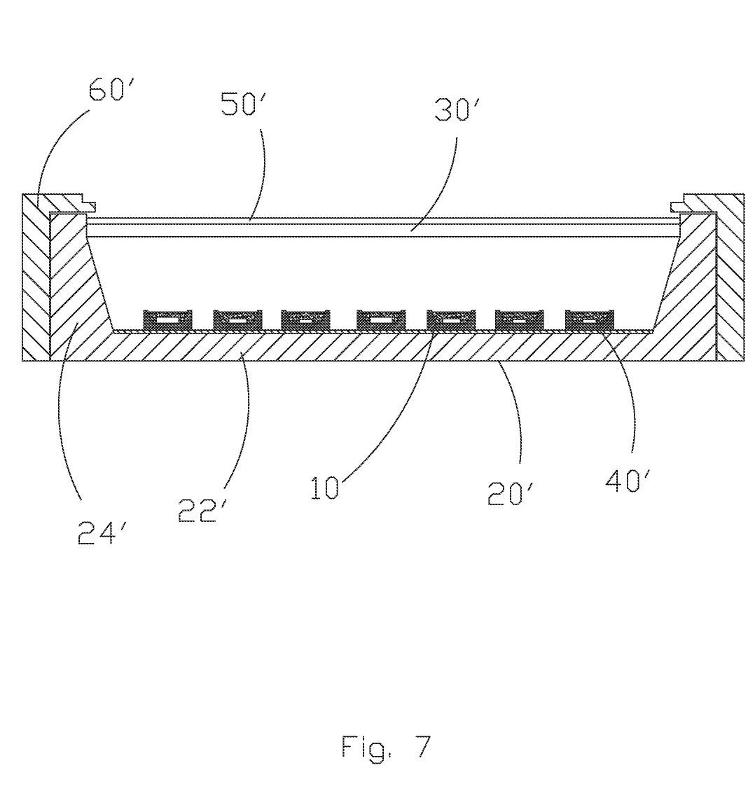

Referring to FIGS. 5 and 7, another embodiment of backlight module according to the present invention is shown. The backlight module comprises a backplane 20′ and LED light bars 10 mounted in the backplane 20′. The backplane 20′ comprises a bottom plate 22′ and side plates 24′ perpendicularly mounted to the bottom plate 22′. Each of the LED light bars 10 comprises a printed circuit board 12 and a plurality of LED lights 14 mounted to and electrically connected to the printed circuit board 12. Each of the LED lights 14 comprises a light-emitting die 142. Differences among the luminous intensities of the light-emitting dies 142 of the plurality of LED lights 14 are less than 5% and the light-emitting dies 142 are of at least two sizes. The plurality of LED lights 14 is of an identical encapsulated size.

Generally, the larger the size of the light-emitting die 142 is, greater the luminous intensity will be. However, due to variation of manufacturing process, the light-emitting dies 142 have various luminous intensities that are located within a predetermined range of variation. For a specific planar light source that is composed of light sources formed of the LED light bar 10, it only needs the variation of luminous intensity of each LED light 14 located within a range of 5% to ensure homogeneity of illumination of the planar light source. This allows the present invention to use, in combination, light-emitting dies 142 of different sizes to form an LED light bar 10, which is then subjected to identical encapsulation operation so as to provide multiple LED lights 14 of the same encapsulation size, eliminating waste of material and reducing manufacture cost.

Each LED light 14 also comprises a carrier frame 144, copper foils (not shown) mounted to the carrier frame, and an encapsulation resin 146. The light-emitting die 142 is arranged inside the carrier frame 144 and is electrically connected by gold wires (not shown) to the copper foils. The encapsulation resin 146 encapsulates the light-emitting die 142 in the carrier frame 144. The encapsulation resin 146 contains fluorescent powders mixed therein to improve the luminous intensity of the LED light 14.

In the instant embodiment, the backlight module further comprises a diffusion plate 30′ disposed above the bottom plate 22′, a reflector plate 40′ disposed between the bottom plate 22′ and the diffusion plate 30′, optic films 50′ disposed on the diffusion plate 30′, and a mold frame 60′ mounted to the backplane 20′. The LED light bars 10 are mounted to the bottom plate 22′ and located below the diffusion plate 30′ so as to form a direct backlight module.

The present invention provides a backlight module, which uses the LED light bar described above so as to reduce the manufacture cost while ensuring homogeneity of illumination.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing a light-emitting diode (LED) light bar, comprising the following steps:
Step 1: providing light-emitting dies of different sizes;
Step 2: measuring luminous intensities of the light-emitting dies;
Step 3: selecting among the light-emitting diodes ones of which the luminous intensities are different from each other by less than 5%;
Step 4: encapsulating the selected ones of the light-emitting dies to form LED lights, which are of substantially identical encapsulated size; and
Step 5: mounting and electrically connecting the LED lights to a printed circuit board to form an LED light bar.

2. An LED (Light-Emitting Diode) light bar, comprising a printed circuit board and a plurality of LED lights mounted to and electrically connected to the printed circuit board, each of the LED lights comprising a light-emitting die, the light-emitting dies of the plurality of LED lights being of at least two sizes, the luminous intensities of the light-emitting dies being different from each other by less than 5%.

3. The LED light bar as claimed in claim 2, wherein the plurality of LED lights is of an identical encapsulated size.

4. The LED light bar as claimed in claim 2, wherein each of the LED lights comprises a carrier frame, copper foils mounted to the carrier frame, and an encapsulation resin, the light-emitting die being arranged inside the carrier frame and electrically connected by gold wires to the copper foils, the encapsulation resin encapsulating the light-emitting die in the carrier frame.

5. A backlight module, comprising a backplane and an LED (Light-Emitting Diode) light bar mounted in the backplane, the LED light bar comprising a printed circuit board and a plurality of LED lights mounted to the printed circuit board, each of the LED lights comprising a light-emitting die, the light-emitting dies of the plurality of LED lights being of at least two sizes, the luminous intensities of the light-emitting dies being different from each other by less than 5%, the plurality of LED lights being of an identical encapsulated size.

6. The backlight module as claimed in claim 5, wherein each of the LED lights comprises a carrier frame, copper foils mounted to the carrier frame, and an encapsulation resin, the light-emitting die being arranged inside the carrier frame and electrically connected by gold wires to the copper foils, the encapsulation resin encapsulating the light-emitting die in the carrier frame.

7. The backlight module as claimed in claim 5, wherein the backplane comprises a bottom plate and a side plate perpendicularly mounted to the bottom plate.

8. The backlight module as claimed in claim 7 further comprising a light guide plate disposed above the bottom plate, a reflector plate disposed between the bottom plate and the light guide plate, optic films disposed on the light guide plate, and a mold frame mounted to the backplane, the LED light bar being mounted to the side plate.

9. The backlight module as claimed in claim 7 further comprising a diffusion plate disposed above the bottom plate, a reflector plate disposed between the bottom plate and the diffusion plate, optic films disposed on the diffusion plate, and a mold frame mounted to the backplane, the LED light bar being mounted to the bottom plate and located below the diffusion plate.
